(19) United States
(12) Patent Application Publication
(10) Pub. No.: US 2025/0051959 A1
(43) Pub. Date: Feb. 13, 2025

(54) EPITAXIAL WAFER MANUFACTURING METHOD AND EPITAXIAL WAFER MANUFACTURING APPARATUS

(71) Applicant: SUMCO CORPORATION, Tokyo (JP)

(72) Inventors: Masayuki TSUJI, Tokyo (JP); Kazuhiro NARAHARA, Tokyo (JP)

(73) Assignee: SUMCO CORPORATION, Tokyo (JP)

(21) Appl. No.: 18/722,963

(22) PCT Filed: Dec. 16, 2022
(86) PCT No.: PCT/JP2022/046358

§ 371 Date: Jun. 21, 2024

(30) Foreign Application Priority Data
Dec. 27, 2021 (JP) 2021-213118

(51) Int. Cl. C30B 25/16; C23C 16/44; C23C 16/46; C23C 16/52; C30B 25/10; H01L 21/66; H01L 21/67

(52) U.S. Cl. CPC C30B 25/16; C23C 16/4405; C23C 16/46; C23C 16/52; C30B 25/105; H01L 21/67248; H01L 22/12

(57) ABSTRACT

A manufacturing method of epitaxial wafers is provided, where an epitaxial wafer manufacturing process including loading a wafer into a chamber of an epitaxial wafer manufacturing apparatus, growing an epitaxial film on the wafer to manufacture an epitaxial wafer, and unloading the epitaxial wafer to an outside of the chamber, is performed for a plurality of times and, subsequently, an interior of the chamber is cleaned. While the epitaxial film is grown, the wafer supported by the susceptor is heated by a first heater and an outer rim portion of the susceptor is heated by a second heater.

### TECHNICAL FIELD

The present invention relates to a manufacturing method of an epitaxial wafer and an epitaxial wafer manufacturing apparatus, in which an epitaxial film is grown on a wafer by vapor phase epitaxy.

### BACKGROUND ART

In a typically known epitaxial wafer manufacturing apparatus for growing an epitaxial film on a wafer, a material gas introduced into a chamber is thermally decomposed or reduced to produce a material, which is grown on a wafer heated at a high temperature by vapor phase epitaxy to form an epitaxial film.

The temperature is strictly controlled during the epitaxial growth process so that defects such as dislocations and atomic level distortion in single crystals are not generated.

Patent Literature 1 discloses a method including measuring a temperature of an outer peripheral portion of an epitaxial wafer and measuring a temperature of a susceptor, where the susceptor or the epitaxial wafer is heated so that a temperature difference between the outer peripheral portion of the epitaxial wafer and the temperature of the susceptor falls within a predetermined range, thereby reducing dislocations at a part of the epitaxial wafer in contact with the susceptor.

### CITATION LIST

### Patent Literature(s)

Patent Literature 1: JP 2010-141060 A

### SUMMARY OF THE INVENTION

### Problem(s) to be Solved by the Invention

According to a typical manufacturing method of an epitaxial wafer, an interior of a chamber is cleaned after loading a wafer into the chamber, growing the epitaxial film, and unloading the wafer.

Meanwhile, in view of disadvantage in terms of a total production cost in cleaning the chamber each time the wafer is unloaded, a multi-wafer deposition process has been known where the chamber is cleaned after repeating a plurality of epitaxial wafer manufacturing processes each consisting of loading a wafer, growing an epitaxial film, and unloading the wafer. In other words, in the manufacturing method of an epitaxial wafer using the multi-wafer deposition process, the chamber is less frequently cleaned in order to reduce the production cost.

However, when the technique disclosed in Patent Literature 1 is applied to the multi-wafer deposition process, distortions are caused on the wafer even by strictly controlling the temperature.

An object of the invention is to provide a manufacturing method of an epitaxial wafer and an epitaxial wafer manufacturing apparatus capable of reducing distortions on a wafer in manufacturing an epitaxial wafer by multi-wafer deposition process.

### Means for Solving the Problem(s)

The inventors have presumed that the cause of the distortions of the wafer in manufacturing the epitaxial wafer by multi-wafer deposition process is attributable to a variation in temperature at an outer rim portion of the susceptor due to a by-product (e.g. polysilicon) deposited on the outer rim portion of the susceptor in growing the epitaxial film. Therefore, the inventors have devised a manufacturing method and apparatus in consideration of the deposition of the by-product, thereby arriving at the invention capable of preventing distortions of wafers.

According to an aspect of the invention, a manufacturing method of epitaxial wafers includes: performing an epitaxial wafer manufacturing process including loading a wafer into a chamber of an epitaxial wafer manufacturing apparatus, growing an epitaxial film on the wafer to manufacture an epitaxial wafer, and unloading the epitaxial wafer to an outside of the chamber; repeating the epitaxial wafer manufacturing process for a plurality of times; and subsequently, cleaning an interior of the chamber, in which the wafer supported by a susceptor is heated by a first heater and an outer rim portion of the susceptor is heated by a second heater while the epitaxial film is grown.

In the manufacturing method according to the above aspect, it is preferable that a temperature of an outer peripheral portion of the wafer or the outer rim portion of the susceptor is measured and the outer rim portion of the susceptor is heated by the second heater based on the measured temperature.

In the manufacturing method according to the above aspect, it is preferable that the temperature of the outer rim portion of the susceptor is measured and the outer rim portion of the susceptor is heated by the second heater so that a temperature difference between a temperature of a central portion of the wafer and the temperature of the outer rim portion of the susceptor does not vary between the wafers.

In the manufacturing method according to the above aspect, the outer rim portion of the susceptor is optionally heated by the second heater under a preset heating condition.

According to another aspect of the invention, a manufacturing method of epitaxial wafers includes: performing an epitaxial wafer manufacturing process including loading a wafer into a chamber of an epitaxial wafer manufacturing apparatus, growing an epitaxial film on the wafer to manufacture an epitaxial wafer, and unloading the epitaxial wafer to an outside of the chamber; repeating the epitaxial wafer manufacturing process for a plurality of times; and subsequently, cleaning an interior of the chamber, in which the wafer supported by a susceptor is heated by a first heater and a temperature of an outer peripheral portion of the wafer or an outer rim portion of the susceptor is measured, and the outer peripheral portion of the wafer is heated by a second heater based on the measured temperature while the epitaxial film is grown.

In the manufacturing method according to the above aspect, the temperature of the outer peripheral portion of the wafer is optionally measured and the outer peripheral portion of the wafer is optionally heated so that a temperature difference between a temperature of a central portion of the wafer and the temperature of the outer peripheral portion thereof does not vary between the wafers.

In the manufacturing method according to the above aspect, the outer peripheral portion of the wafer is optionally heated by the second heater under a preset heating condition.

According to still another aspect of the invention, an epitaxial wafer manufacturing apparatus includes: a first heater configured to heat a wafer supported by a susceptor; a temperature sensor configured to measure a temperature of an outer peripheral portion of the wafer or an outer rim portion of the susceptor; a second heater configured to heat the outer rim portion of the susceptor; and a controller configured to control the second heater based on the temperature.

In the epitaxial wafer manufacturing apparatus according to the above aspect, the second heater is preferably a laser heater.

According to a further aspect of the invention, an epitaxial wafer manufacturing apparatus includes: a first heater configured to heat a wafer supported by a susceptor; a temperature sensor configured to measure a temperature of an outer peripheral portion of the wafer or an outer rim portion of the susceptor; a second heater configured to heat the outer peripheral portion of the wafer; and a controller configured to control the second heater based on the temperature.

### BRIEF EXPLANATION OF DRAWING(S)

FIG. 1 schematically depicts an epitaxial wafer manufacturing apparatus according to a first exemplary embodiment of the invention.

FIG. 2 is a cross-sectional view depicting a susceptor of the epitaxial wafer manufacturing apparatus according to the first exemplary embodiment of the invention.

FIG. 3 is a flowchart showing a manufacturing method of an epitaxial wafer according to the first exemplary embodiment of the invention.

FIG. 4 is a flowchart showing an epitaxial-film formation step according to the first exemplary embodiment of the invention.

FIG. 5 schematically depicts an epitaxial wafer manufacturing apparatus according to a second exemplary embodiment of the invention.

### DESCRIPTION OF EMBODIMENT(S)

Description will be made on a mode for carrying out the invention with reference to the attached drawings.

### First Exemplary Embodiment

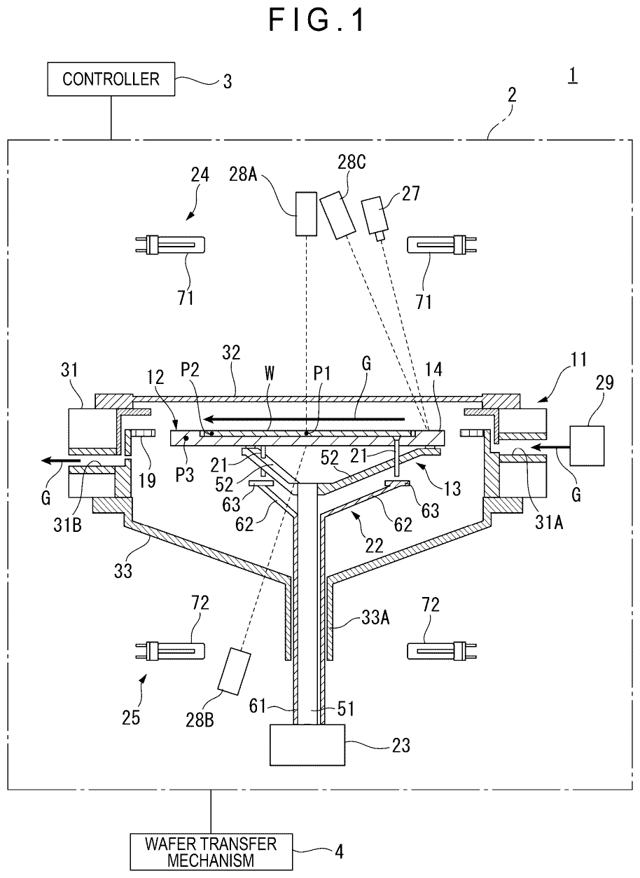

FIG. 1 schematically depicts an epitaxial wafer manufacturing apparatus according to a first exemplary embodiment of the invention.

As shown in FIG. 1, an epitaxial wafer manufacturing apparatus 1, which is a single-wafer processing machine for processing a wafer W one by one, includes a machine body 2, a controller 3, and a wafer transfer mechanism 4.

Examples of the wafer W include silicon wafer, GaAs wafer, InP wafer, ZnS wafer, ZnSe wafer, and SOI wafer.

The machine body 2 includes a chamber 11 for the wafer W to be loaded into, a susceptor 12 horizontally supporting the wafer W from a lower side thereof within the chamber 11, a support drive mechanism 23, and a gas feeder 29. The susceptor 12 is rotatably supported by a susceptor support 13.

The chamber 11 includes an annular base 31, an upper dome 32 covering an upper side of the loaded wafer W, and a lower dome 33 covering a lower side of the wafer W.

The base 31 is provided with a gas inlet 31A for introducing a gas G into the chamber 11 and a gas outlet 31B for discharging the gas G out of the chamber 11, the gas inlet 31A and the gas outlet 31B being horizontally opposed.

The gas feeder 29 is configured to introduce a material gas (e.g. trichlorosilane (SiHCl3)) together with a carrier gas (e.g. hydrogen (H2)) and, as necessary, a dopant gas (e.g. diborane (B2H6)) through the gas inlet 31A into an upper space within the chamber 11. These gases are discharged through the gas outlet 31B.

A heat ring 19 configured to preheat the susceptor 12 and the introduced gas G is attached to an inner side of the base 31. The heat ring 19 preheats the susceptor 12 and trichlorosilane before trichlorosilane is in contact with the wafer W. This improves thermal uniformity of the wafer W before and during the film-formation process and, consequently, uniformity of the epitaxial film. The heat ring 19 also restrains the gas G from flowing into a lower part of the chamber 11.

The heat ring 19 can be made of, for instance, a carbon material covered with silicon carbide (SIC).

A hollow cylinder 33A is formed extending downwardly at the center of the lower dome 33. An inner column 51 and an outer column 61 are placed through the hollow cylinder 33A. The inner column 51 is a part of the susceptor support 13 supporting the susceptor 12. The outer column 61 is a part of a lift pin support 22 is axially slidably provided on an outer circumferential surface of the inner column 51. Outer arms 62 are provided at an upper end of the outer column 61

The base 31 can be made of, for instance, a stainless steel. The upper dome 32 and the lower dome 33 can be made of, for instance, transparent quartz that does not block heat rays (e.g. infrared rays) from an upper lamp 24 (first heater) and a lower lamp 25 (first heater) for heating the wafer W and the susceptor 12 within the chamber 11.

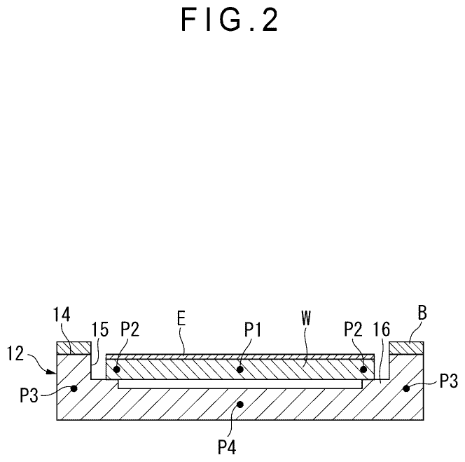

The susceptor 12 is a disc-shaped component for the wafer W to be placed within the chamber 11. As depicted in FIG. 2, an annular outer rim portion 14 is provided at an outermost of the upper side of the susceptor 12, where an inner circumference of the outer rim portion 14 defines a circular concave 15. The concave 15, in which the wafer W is to be placed, has a diameter slightly larger than the diameter of the wafer W. A projection 16 protruding upward with respect to a bottom face of the concave 15 is provided at an outermost peripheral portion of the concave 15. The projection 16 supports an outer rim portion of the wafer W. The heat ring 12 can be made of, for instance, a carbon material covered with silicon carbide.

As depicted in FIG. 1, the susceptor support 13 supports the susceptor 12 with the cylindrical inner column 51 and a plurality of arms 52 radially extending from a tip end of the inner column 51.

Each of the lift pins 21 includes a cylindrical shaft and an upwardly flared truncated conical head provided at an upper end of the shaft. The head of each of the lift pins 21 is supported by the susceptor 12.

The lift pins 21 can be made of, for instance, silicon carbide, quartz, carbon material, glass carbon, or a carbon material covered with silicon carbide.

Each of the lift pins 21 is vertically slidable with a lower end thereof being supported by the lift pin support 22.

The lift pin support 22 includes the cylindrical outer column 61, the plurality of outer arms 62 radially extending from the end of the outer column 61, and contact portions 63 each provided to an end of the corresponding one of the outer arms 62. When the lift pins 21 are moved, the contact portions 63 support corresponding one-to-one to the lift pins 21 in contact therewith.

The support drive mechanism 23 is configured to rotate the susceptor support 13 and vertically move the lift pin support 22.

A first pyrometer 28A is attached above the center of the wafer W and above the chamber 11. The first pyrometer 28A is configured to detect heat radiation from the wafer W to measure a surface temperature of the wafer W in a non-contact manner.

The upper lamp 24, which is configured to heat the wafer W and the susceptor 12 from above, is also provided above the chamber 11.

A second pyrometer 28B is attached under the chamber 11. The second pyrometer 28B is configured to measure a temperature of a central portion of the susceptor 12 in a non-contact manner.

The lower lamp 25, which is configured to heat the susceptor 12 from under, is also provided under the chamber 11.

The upper lamp 24 are provided by a plurality of upper halogen lamps 71 horizontally laid in a ring. The lower lamp 25 are provided by a plurality of lower halogen lamps 72 horizontally laid in a ring. It should be noted that the upper lamp 24 and the lower lamp 25, which are not necessarily arranged as described above, are optionally otherwise arranged, where, for instance, one or more ring arrays of halogen lamps are provided at an inner side of the lower halogen lamps 72 in order to increase the heat from below.

In addition to the first pyrometer 28A and the second pyrometer 28B, a third pyrometer 28C (temperature sensor) for measuring a temperature of an outer rim portion 14 of the susceptor 12 is provided above the chamber 11. In order to avoid interference with the upper lamp 24, the third pyrometer 28C is not provided immediately above the outer rim portion 14 of the susceptor 12 but provided at an inner side of the upper lamp 24. The third pyrometer 28C is optionally provided outside the upper lamp 24.

An auxiliary heater 27 (second heater) for heating the outer rim portion 14 of the susceptor 12 is also provided above the chamber 11. The auxiliary heater 27 is oriented to heat the outer rim portion 14 of the susceptor 12.

The auxiliary heater 27 is preferably a directional device capable of concentrating heat on a small point, which is approximately 10 mm in diameter, using light collection function of a lens. The auxiliary heater 27 is optionally a laser heater such as YAG laser and YLF laser. Another example of the auxiliary heater 27 is a heater for heating an object using radiation heat of infrared rays.

The machine body 2 of the present exemplary embodiment is provided with one third pyrometer 28C and one auxiliary heater 27. The third pyrometer 28C and the auxiliary heater 27 are pointed at a single point on the outer rim portion 14 of the susceptor 12. With the rotation of the susceptor 12, an entire circumference of the outer rim portion 14 can be measured by the third pyrometer 28C and can be heated by the auxiliary heater 27. It should be noted that the third pyrometer 28C and the auxiliary heater 27 are optionally provided in plural. Additionally, the auxiliary heater 27 is optionally provided under the chamber 11.

The controller 3 is configured to control the wafer transfer mechanism 4, the support drive mechanism 23, the upper lamp 24, the lower lamp 25, the auxiliary heater 27, and the gas feeder 29.

A manufacturing program relating to a process sequence and control parameters (control target values such as a temperature, pressure, type and flow rate of gases, and film-formation time) for manufacturing the epitaxial wafer, which include a process sequence for controlling the temperature (especially, a preset temperature of the wafer W within the chamber 11) and data (e.g. a calibration curve of a growth temperature), are stored in a storage of the controller 3.

In manufacturing the epitaxial wafer, the controller 3 reads out the manufacturing program from the storage to control the wafer transfer mechanism 4, the support drive mechanism 23, the upper lamp 24, the lower lamp 25, and the gas feeder 29.

In order to control the temperature, the controller 3 reads out the manufacturing program to control the temperature (especially, the preset temperature of the wafer W within the chamber 11) based on the manufacturing program and the measurement data.

The wafer transfer mechanism 4 loads the wafer W into the chamber 11 and unloads the wafer W out of the chamber 11 through a wafer loading/unloading port (not illustrated) of the chamber 11.

### Manufacturing Method of Epitaxial Wafer

Next, a manufacturing method of the epitaxial wafer using the epitaxial wafer manufacturing apparatus 1 will be described below.

According to the manufacturing method of the epitaxial wafer, the epitaxial film is sequentially formed on a plurality of wafers W using the epitaxial wafer manufacturing apparatus 1.

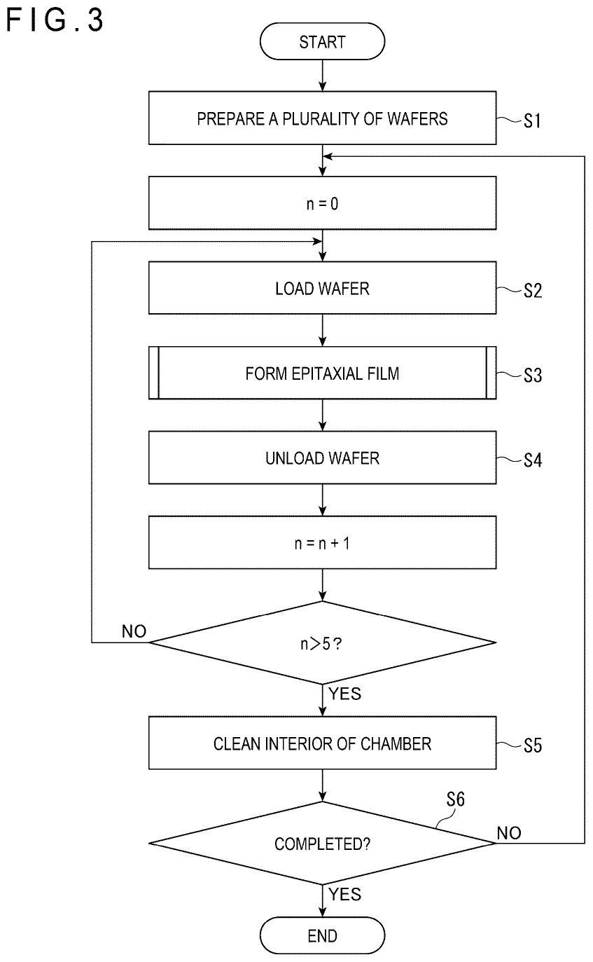

As depicted in FIG. 3, the manufacturing method of the epitaxial wafer includes a wafer-preparation step S1 for preparing a plurality of wafers W, a wafer import step S2 for loading one of the wafers W, an epitaxial-film formation step S3 for forming an epitaxial film E on the loaded wafer W, a wafer export step S4 for unloading the wafer W, a cleaning step S5 for cleaning an interior of the chamber 11, and a determination step S6 for determining whether the epitaxial film E has been grown on all of the prepared wafers W (i.e. whether the process has completed).

Herein, the three steps of the wafer import step S2, the epitaxial-film formation step S3, and the wafer export step S4 will be collectively referred to as an epitaxial wafer manufacturing process.

According to the manufacturing method of the epitaxial wafer of the present exemplary embodiment, it is programmed to perform the cleaning step S5 after repeating the epitaxial wafer manufacturing process for five times.

It should be noted that the number of the epitaxial wafer manufacturing processes performed before the cleaning step S5, which is five in the present exemplary embodiment, may be any plural number in a range from, for instance, two to nine.

In other words, the manufacturing method of the epitaxial wafer of the invention is a method using the multi-wafer deposition process, where the chamber is cleaned after repeating a plurality of epitaxial wafer manufacturing processes each consisting of loading of the wafer W, growing the epitaxial film E, and unloading the wafer W.

The wafer-preparation step S1 is a step for preparing the wafer W. The diameter of the wafer W may be determined as desired (e.g. 200 mm, 300 mm, 450 mm).

In the wafer import step S2, the controller 3 controls the wafer transfer mechanism 4 to load the wafer W into the chamber 11 through the wafer loading/unloading port (not shown) of the chamber 11 and stops the wafer W above the concave 15 of the susceptor 12. Subsequently, the controller 3 controls the support drive mechanism 23 to raise the lift pin support 22 and, consequently, the lift pins 21 supported by the susceptor 12, thereby lifting the wafer W to receive the wafer W from the wafer transfer mechanism 4.

Next, the controller 3 controls the support drive mechanism 23 to lower the lift pin support 22, thereby placing the wafer W into the concave 15 of the susceptor 12.

Details of the epitaxial-film formation step S3 will be described below. The epitaxial-film formation step S3 is a step for growing the epitaxial film E on the loaded wafer W to form an epitaxial wafer.

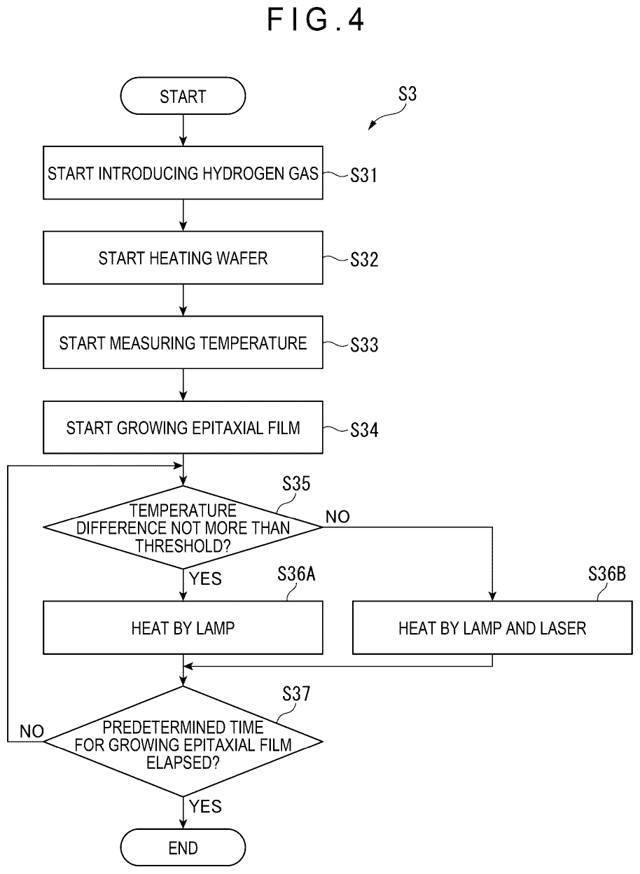

As illustrated in FIG. 4, the epitaxial-film formation step S3 includes a gas introduction step S31, a wafer heating step S32, a temperature measurement step S33, an epitaxial film growth step S34, a temperature difference determination step S35, a heating step S36, and a growth-time determination step S37.

In the gas introduction step S31, the controller 3 controls the gas feeder 29 to start introducing hydrogen gas (carrier gas) through the gas inlet 31A. While continuously introducing the hydrogen gas, the controller 3 discharges the hydrogen gas through the gas outlet 31B to form a hydrogen atmosphere in the chamber 11. Simultaneously with introducing the hydrogen gas, the controller 3 also controls the support drive mechanism 23 to rotate the susceptor support 13.

In the wafer heating step S32, while controlling the first pyrometer 28A to measure a surface temperature of the wafer W, the controller 3 controls the upper lamp 24 and the lower lamp 25 to further heat the wafer W to a preset temperature for forming a film. In the present exemplary embodiment, trichlorosilane (SiHCl3) is used as the material gas and the preset temperature for forming a film is set in a temperature range lower than 1,200 degrees C.

In the temperature measurement step S33, the temperature of the central portion P1 of the wafer W is measured using the first pyrometer 28A and the temperature of the outer rim portion 14 of the susceptor 12 is measured using the third pyrometer 28C.

In the epitaxial film growth step S34, while measuring the surface temperature of the wafer W using the first pyrometer 28A, the controller 3 controls the upper lamp 24 and the lower lamp 25 to raise the temperature within the chamber 11 and controls the gas feeder 29 to feed trichlorosilane to an upper space in the chamber 11 through the gas inlet 31A.

When the rotation of the susceptor 12 and the temperature of the wafer W are stabilized, various gases are fed to uniformly grow the epitaxial film E on the wafer W.

Next, the temperature difference determination step S35 and the heating step S36 will be described below.

Initially, description will be made on a by-product B generated while the epitaxial film E is grown and how the auxiliary heater 27 is controlled.

During the growth of the epitaxial film E, the by-product B (polysilicon, see FIG. 2) generated in accordance with the epitaxial film growth process is deposited on the outer rim portion 14 of the susceptor 12. The by-product B deposited on the outer rim portion 14 of the susceptor 12 reduces heating efficiency of the outer rim portion of the susceptor 12 by the upper lamp 24.

Specifically, when only a small amount of the by-product B is deposited, a difference between the temperature of the central portion P1 of the wafer W and the temperature of the inner portion P3 of the outer rim portion 14 of the susceptor 12 is small. Consequently, a difference between the temperature of the central portion P1 of the wafer W and the temperature of the outer peripheral portion P2 of the wafer W also becomes small.

However, since the by-product B is low in terms of absorptivity for infrared rays emitted by the lamp, the inner portion P3 of the outer rim portion 14 of the susceptor 12 is not easily heated when much amount of the by-product B is deposited. The difference between the temperature of the central portion P1 of the wafer W and the temperature of the inner portion P3 of the outer rim portion 14 of the susceptor 12 is thus increased, so that the difference between the temperatures of the central portion P1 and the outer peripheral portion P2 of the wafer W, which is in contact with the outer rim portion 14 of the susceptor 12 via the projection 16, is also increased. Due to the temperature difference between the central portion P1 and the outer peripheral portion P2 of the wafer W, the wafer W is distorted at an atomic level and/or the thickness of the epitaxial film E is reduced at the outer peripheral portion P2 of the wafer W.

It should be noted that the distortion of the wafer W can be measured using a distortion measurement device (SIRD device) using infrared photoelasticity.

It should also be noted that the “outer peripheral portion of the wafer W” refers to a peripheral portion extending from an outer circumference to 3% of a diameter of a disc-shaped wafer W.

In order to restrain the distortion, the controller 3 measures the temperature of the outer rim portion 14 of the susceptor 12 using the third pyrometer 28C and controls the auxiliary heater 27 to heat the outer rim portion 14 of the susceptor 12 based on the measured temperature.

Specifically, in the temperature difference determination step S35, it is determined whether the temperature difference between the temperature of the central portion P1 of the wafer W and the temperature of the outer rim portion 14 of the susceptor 12 measured in the temperature measurement step S33 is equal to or less than a predetermined threshold (e.g. 5 degrees C.).

When the temperature difference is equal to or less than the predetermined threshold, the wafer W is kept being heated only by the lamps without using the auxiliary heater 27 (heating step S36A). In contrast, when the temperature difference exceeds the predetermined threshold, the outer rim portion 14 of the susceptor 12 is heated (laser heating) additionally using the auxiliary heater 27 as well as the lamps (heating step S36B).

In other words, in order to compensate for the decrease in the heating efficiency of the outer rim portion 14 of the susceptor 12 caused by the deposited by-product B, the controller 3 controls to heat the outer rim portion 14 of the susceptor 12 so that the temperature difference between the temperature of the central portion P1 of the wafer W and the temperature of the inner portion P3 of the outer rim portion of the susceptor 12 does not vary between the plurality of wafers W to be manufactured.

The control process of the auxiliary heater 27 based on the temperature of the outer rim portion 14 of the susceptor 12 is optionally performed in all of the epitaxial wafer manufacturing processes (i.e. throughout the first to fifth epitaxial wafer manufacturing processes) or, alternatively, is performed in the second and subsequent epitaxial wafer manufacturing processes without being performed in the first epitaxial wafer manufacturing process.

In the growth-time determination step S37, whether a predetermined epitaxial film growth time has elapsed is determined. When the predetermined epitaxial film growth time has elapsed, the epitaxial-film formation step S3 is ended, whereas the growth of the epitaxial film E is continued when the predetermined epitaxial film growth time has not elapsed.

Next, the wafer export step S4, the cleaning step S5, and the determination step S6 will be described below with reference to FIG. 3.

After the epitaxial film E is formed, in the wafer export step S14, while controlling the first pyrometer 28A to measure the surface temperature of the wafer W, the controller 3 controls the upper lamp 24 and the lower lamp 25 to lower the temperature of the wafer W from the preset temperature for forming a film to a preset temperature for unloading the wafer. Then, the controller 3 controls the support drive mechanism 23 to raise the lift pin support 22, thereby lifting up the wafer W from the susceptor 12 by the lift pins 21. Subsequently, the controller 3 controls the wafer transfer mechanism 4 so that the wafer transfer mechanism 4 is moved into the chamber 11 and stopped at a position under the wafer W.

Then, the controller 3 lowers the lift pin support 22 by controlling the support drive mechanism 23 to deliver the wafer W to the wafer transfer mechanism 4. Subsequently, the controller 3 controls the wafer transfer mechanism 4 to unload the wafer W to an outside of the chamber 11.

Next, the controller 3 controls the wafer transfer mechanism 4 to load another wafer W into the chamber 11 and then performs the same process as the above-described series of steps to manufacture another epitaxial wafer.

After performing the above-described epitaxial wafer manufacturing process for five times to manufacture five epitaxial wafers, the controller 3 performs the cleaning step S5.

The cleaning step S5 is a step for supplying hydrogen chloride gas into the chamber 11 through the gas inlet 31A to clean the interior of the chamber 11. The introduced hydrogen chloride gas reacts with the by-product B to etch and remove the by-product B.

In the determination step S6, whether the epitaxial film E is formed on all of the prepared wafers W is determined and, when the epitaxial film E has been formed on all of the wafers W, the manufacturing method of the epitaxial wafer is ended.

According to the above-described exemplary embodiment, in the so-called multi-wafer deposition process where the cleaning step is performed after performing the epitaxial wafer manufacturing processes for a plurality of times, the outer rim portion 14 of the susceptor 12 is heated based on the temperature of the outer rim portion 14 of the susceptor 12 to reduce variation in the temperature difference between the temperature of the central portion P1 of the wafer W and the temperature of the inner portion P3 of the outer rim portion 14 of the susceptor 12. The distortions of the wafer W caused by the temperature difference between the temperature of the central portion P1 of the wafer W and the temperature of the outer peripheral portion P2 of the wafer W can thus be reduced.

Further, since not the wafer W but the outer rim portion 14 of the susceptor 12 is heated, the invention is applicable in manufacturing wafers, in which slip dislocations and the like occur when the wafers are directly heated.

Further, with the use of the laser heater as the auxiliary heater 27, only the surface of the outer rim portion 14 of the susceptor 12 can be intensively heated.

### Second Exemplary Embodiment

A manufacturing method of an epitaxial wafer and an epitaxial wafer manufacturing apparatus according to a second exemplary embodiment of the invention will be described below. It should be noted that the description for the same components as those in the first exemplary embodiment will be omitted in the present exemplary embodiment.

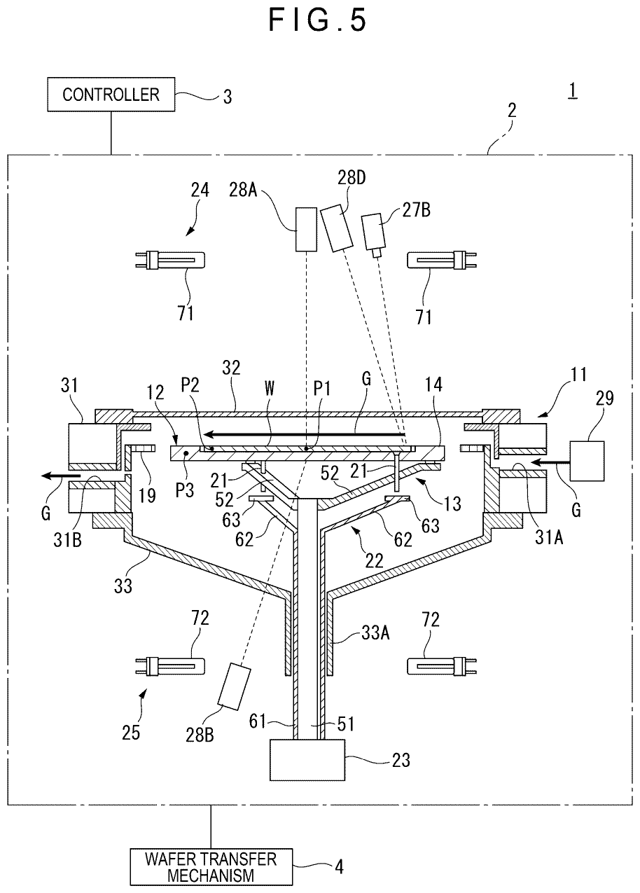

In the above-described first exemplary embodiment, the auxiliary heater 27 is configured to heat the outer rim portion 14 of the susceptor 12. In contrast, as depicted in FIG. 5, an auxiliary heater 27B of the present exemplary embodiment is configured to heat the outer peripheral portion P2 of the wafer W. Specifically, the auxiliary heater 27B of the present exemplary embodiment is oriented to heat the outer peripheral portion P2 of the wafer W.

Further, a third pyrometer 28D of the present exemplary embodiment is oriented to measure the temperature of the outer peripheral portion P2 of the wafer W.

The controller 3 of the present exemplary embodiment is configured to control the auxiliary heater 27B based on the temperature of the outer peripheral portion P2 of the wafer W measured by the third pyrometer 28D to heat the outer peripheral portion P2 of the wafer W.

Specifically, the controller 3 is configured to heat the outer peripheral portion P2 of the wafer W so that the temperature difference between the temperature of the central portion P1 of the wafer W and the temperature of the outer peripheral portion P2 of the wafer W does not vary.

According to the above-described exemplary embodiment, the outer peripheral portion P2 of the wafer W is directly heated, so that the temperature of the outer peripheral portion P2 of the wafer W can be more quickly changed to eliminate unnecessary thermal distortions.

It should be noted that the auxiliary heater 27, which is controlled so that the temperature difference between the temperature of the central portion P1 of the wafer W and the temperature of the outer rim portion 14 of the susceptor 12 (or the outer peripheral portion P2 of the wafer W) does not vary in the above exemplary embodiments, is not necessarily configured as described above. For instance, the temperature is optionally not measured during the manufacturing process of the epitaxial wafer but the auxiliary heater 27 is optionally controlled based on preset heating conditions.

Specifically, in order to determine the heating conditions of the outer rim portion 14 of the susceptor 12 in advance, the epitaxial wafer is manufactured for a plurality of times through the multi-wafer deposition process. At this time, the outer rim portion 14 of the susceptor 12 (or the outer peripheral portion P2 of the wafer W) is heated by the auxiliary heater 27 while changing the heating conditions. Then, the heating conditions under which an epitaxial wafer with good quality has been manufactured in each of the epitaxial wafer manufacturing processes are selected as the heating conditions for actually manufacturing the epitaxial wafer.

It should be noted that the heating conditions are optionally determined by measuring the temperatures of the wafer and the susceptor using the pyrometers and checking the temperature difference between the wafer and the susceptor.

Further, though the thickness of the deposited by-product B is not taken into consideration in the above-described exemplary embodiments, the thickness of the by-product B is optionally measured or estimated and a heating amount by the auxiliary heater 27 is optionally changed depending on the thickness.

Further, the auxiliary heater 27, which is controlled based on the temperature of the central portion P1 of the wafer W measured by the first pyrometer 28A and the temperature of the outer rim portion 14 of the susceptor 12 (or the outer peripheral portion P2 of the wafer W) measured by the third pyrometer 28C (28D) in the above exemplary embodiments, is not necessarily configured as described above. For instance, the auxiliary heater 27 is optionally controlled in additional consideration of the temperature of a central portion P4 (see FIG. 2) of the susceptor 12 measured by the second pyrometer 28B.

Further, the auxiliary heater 27 (second heater), which is provided in a form of the laser heater in the above-described exemplary embodiments, is not necessarily configured as described in the exemplary embodiments. For instance, a halogen lamp and xenon lamp are also usable as the auxiliary heater.

### EXPLANATION OF CODES

1 . . . epitaxial wafer manufacturing apparatus, 2 . . . machine body, 3 . . . controller, 4 . . . wafer transfer mechanism, 11 . . . chamber, 12 . . . susceptor, 13 . . . susceptor support, 15 . . . concave, 16 . . . projection, 19 . . . heat ring, 24 . . . upper lamp (first heater), 25 . . . lower lamp (first heater), 27 . . . auxiliary heater (second heater), 28A . . . first pyrometer, 28B . . . second pyrometer, 28C . . . third pyrometer, 29 . . . gas feeder, 31 . . . base, 31A . . . gas inlet, 31B . . . gas outlet, 32 . . . upper dome, 33 . . . lower dome, B . . . by-product, P1 . . . central portion of wafer, P2 . . . outer peripheral portion of wafer, P3 . . . inner portion of outer rim portion of susceptor, P4 . . . central portion of susceptor, W . . . wafer

1. A manufacturing method of epitaxial wafers, the method comprising:
performing an epitaxial wafer manufacturing process comprising loading a wafer into a chamber of an epitaxial wafer manufacturing apparatus, growing an epitaxial film on the wafer to manufacture an epitaxial wafer, and unloading the epitaxial wafer to an outside of the chamber;
repeating the epitaxial wafer manufacturing process for a plurality of times; and
subsequently, cleaning an interior of the chamber, wherein
the wafer supported by a susceptor is heated by a first heater and an outer rim portion of the susceptor is heated by a second heater while the epitaxial film is grown.

2. The manufacturing method of epitaxial wafers according to claim 1, wherein
a temperature of an outer peripheral portion of the wafer or the outer rim portion of the susceptor is measured and the outer rim portion of the susceptor is heated by the second heater based on the measured temperature.

3. The manufacturing method of epitaxial wafers according to claim 2, wherein
the temperature of the outer rim portion of the susceptor is measured and the outer rim portion of the susceptor is heated by the second heater so that a temperature difference between a temperature of a central portion of the wafer and the temperature of the outer rim portion of the susceptor does not vary between the wafers.

4. The manufacturing method of epitaxial wafers according to claim 1, wherein
the outer rim portion of the susceptor is heated by the second heater under a preset heating condition.

5. A manufacturing method of epitaxial wafers, the method comprising:
performing an epitaxial wafer manufacturing process comprising loading a wafer into a chamber of an epitaxial wafer manufacturing apparatus, growing an epitaxial film on the wafer to manufacture an epitaxial wafer, and unloading the epitaxial wafer to an outside of the chamber;
repeating the epitaxial wafer manufacturing process for a plurality of times; and
subsequently, cleaning an interior of the chamber, wherein
the wafer supported by a susceptor is heated by a first heater, a temperature of an outer peripheral portion of the wafer or an outer rim portion of the susceptor is measured, and the outer peripheral portion of the wafer is heated by a second heater based on the measured temperature while the epitaxial film is grown.

6. The manufacturing method of epitaxial wafers according to claim 5, wherein
the temperature of the outer peripheral portion of the wafer is measured and the outer peripheral portion of the wafer is heated so that a temperature difference between a temperature of a central portion of the wafer and the temperature of the outer peripheral portion thereof does not vary between the wafers.

7. The manufacturing method of epitaxial wafers according to claim 5, wherein
the outer peripheral portion of the wafer is heated by the second heater under a preset heating condition.

8. An epitaxial wafer manufacturing apparatus comprising:
a first heater configured to heat a wafer supported by a susceptor;
a temperature sensor configured to measure a temperature of an outer peripheral portion of the wafer or an outer rim portion of the susceptor;
a second heater configured to heat the outer rim portion of the susceptor; and
a controller configured to control the second heater based on the temperature.

9. The epitaxial wafer manufacturing apparatus according to claim 8, wherein the second heater is a laser heater.

10. An epitaxial wafer manufacturing apparatus comprising:
a first heater configured to heat a wafer supported by a susceptor;
a temperature sensor configured to measure a temperature of an outer peripheral portion of the wafer or an outer rim portion of the susceptor;
a second heater configured to heat the outer peripheral portion of the wafer; and
a controller configured to control the second heater based on the temperature.
